(19) United States
(12) Patent Application Publication
(10) Pub. No.: US 2026/0264006 A1
(43) Pub. Date: Sep. 10, 2026

(54) SUBSTRATE-PROCESSING APPARATUS AND EXHAUST GAS-PROCESSING METHOD USING THE SAME

(71) Applicant: WONIK IPS CO., LTD., Pyeongtaek-si, Gyeonggi-do (KR)

(72) Inventors: Kang Hyun SEO, Pyeongtaek-si, Gyeonggi-do (KR); Byoung Guk SON, Pyeongtaek-si, Gyeonggi-do (KR); Kyu Yong WI, Pyeongtaek-si, Gyeonggi-do (KR)

(21) Appl. No.: 18/873,612

(22) PCT Filed: Nov. 6, 2023
(86) PCT No.: PCT/KR2023/017653

§ 371 Date: Dec. 10, 2024

(30) Foreign Application Priority Data
Aug. 30, 2023 (KR) 10-2023-0114535

(51) Int. Cl. B01D 53/32; B01D 46/00; B01D 46/62; C23C 16/455

(52) U.S. Cl. CPC B01D 53/32; B01D 46/0027; B01D 46/62; C23C 16/45544; B01D 2259/818

(57) ABSTRACT

A substrate-processing apparatus includes a process chamber that forms a processing space for substrate processing, a substrate support on which multiple substrates are seated and which is rotatable, a showerhead including a first gas spray part for supplying a first process gas onto the substrate support and a second gas spray part for supplying a second process gas onto the substrate support, a first exhaust part including a first exhaust line that is positioned adjacent to the first gas spray part to exhaust the first process gas, supplied to the processing space, to an outside of the processing space, and a second exhaust part including a second exhaust line that is positioned adjacent to the second gas spray part to exhaust the second process gas, supplied to the processing space, to an outside of the processing space.

### TECHNICAL FIELD

The present invention relates to an apparatus for processing a substrate and a method thereof, and more particularly to a substrate-processing apparatus and an exhaust gas-processing method using the same.

### BACKGROUND ART

Recently, the demand for a thin film with a very thin thickness has been increasing due to the high integration of semiconductor devices, and, as the size of a contact hole is reduced, there is a need for a thin film deposition method with excellent step coverage. An atomic layer deposition (ALD) process is being applied as a deposition method that can overcome these various problems. In particular, when the atomic layer deposition (ALD) process is applied, the thickness of a thin film can be controlled at the atomic or molecular layer level.

In the atomic layer deposition (ALD) process, two methods are being used: a space-division method and a time-division method. An atomic layer deposition process adopting the space-division method is characterized by rotating multiple substrates while process gases are continuously injected, and an atomic layer deposition process adopting the time-division method is characterized by injecting process gases onto a substrate at different times.

In the atomic layer deposition process adopting the space-division method, a source gas exhaust line and a reaction gas exhaust line are independently formed, and an exhaust part is formed to prevent respective gases from meeting and react with each other at a lower exhaust stage.

Here, a source gas exhaust line is configured with a plasma pretreatment device and a trap for powder collection, but source gas, which has not been converted to powder due to the decrease in efficiency of the plasma pretreatment device, is accumulated and causes ignition. Specifically, a powder in a state where the reaction has not been completed comes into contact with moisture in the air at an exhaust stage, causing a reaction, generating flammable gas and causing ignition of this flammable gas.

In addition, a powder may accumulate in a source gas exhaust line and a large amount of powder may fall to a booster pump at once due to vibrations, etc., causing a trip in a pump. Accordingly, if a source gas is exhausted through a reaction gas exhaust line without a plasma pretreatment device, environmental and safety issues may arise.

### DISCLOSURE

### Technical Problem

Therefore, the present invention has been made in view of the above problems, and it is one object of the present invention to provide a substrate-processing apparatus in which a plasma pre-processing part is provided in each exhaust line formed for each area where process gas is supplied, and an exhaust gas-processing method using the substrate-processing apparatus, so that the operation of the plasma pre-processing part can be controlled according to the flow of the source gas, and the environmental safety problem caused by a source gas being discharged into the atmosphere can be improved. However, this object is exemplary and the scope of the present invention is not limited thereto.

### Technical Solution

In accordance with an aspect of the present invention, the above and other objects can be accomplished by the provision of a substrate-processing apparatus, including: a process chamber that forms a processing space for substrate processing; a substrate support which is formed at a lower part of the processing space, on which multiple substrates are seated and which is rotatable; a showerhead which is installed on an upper side of the process chamber to face the substrate support and includes a first gas spray part for supplying a first process gas onto the substrate support and a second gas spray part for supplying a second process gas onto the substrate support; a first exhaust part including a first exhaust line that is positioned adjacent to the first gas spray part to exhaust the first process gas, supplied to the processing space, to an outside of the processing space; and a second exhaust part including a second exhaust line that is positioned adjacent to the second gas spray part to exhaust the second process gas, supplied to the processing space, to an outside of the processing space, wherein the first exhaust part includes a first plasma pretreatment part that forms a plasma atmosphere in some areas of the first exhaust line and converts exhaust gas exhausted to the first exhaust line into a powder form, and the second exhaust part includes a second plasma pretreatment part that forms a plasma atmosphere in some areas of the second exhaust line and converts exhaust gas exhausted to the second exhaust line into a powder form.

According to some embodiments of the present invention, the first exhaust part may include: a first trap formed after the first plasma pretreatment part and configured to capture powder formed in the first plasma pretreatment part; a second trap formed after the first trap and configured to capture residual powder that is not captured by the first trap; and a first pump configured to suck exhaust gas of the processing space from an inside of the processing space and exhaust it to an outside of the processing space, through the first exhaust line.

According to some embodiments of the present invention, the second exhaust part may include: a third trap formed after the second plasma pretreatment part and configured to capture powder formed in the second plasma pretreatment part; and a second pump configured to suck exhaust gas of the processing space from an inside of the processing space and exhaust it to an outside of the processing space, through the second exhaust line.

According to some embodiments of the present invention, the substrate-processing apparatus may include a gas sensor located at the second exhaust line and configured to sense that the first process gas sprayed from the first gas spray part is introduced into the second exhaust line.

According to some embodiments of the present invention, the substrate-processing apparatus may include a controller configured to control an operation of the second plasma pretreatment part depending upon whether the first process gas is sensed by the gas sensor.

According to some embodiments of the present invention, the controller may turn off the second plasma pretreatment part when the first process gas is not sensed by the gas sensor, and may operate the second plasma pretreatment part such that the first process gas exhausted to the second exhaust line is converted into a powder form when the first process gas is sensed by the gas sensor.

In accordance with an aspect of the present invention, the above and other objects can be accomplished by the provision of an exhaust gas-processing method using a substrate-processing apparatus, the substrate-processing apparatus including: a process chamber forming a processing space for substrate processing; a substrate support which is formed under the processing space, on which multiple substrates S are seated, and which is rotatable; a showerhead including a first gas spray part which is installed on an upper side of the process chamber to face the substrate support and supplies a first process gas onto the substrate support; and a second gas spray part which supplies a second process gas onto the substrate support; a first exhaust part including a first plasma pretreatment part that forms a plasma atmosphere in some areas of a first exhaust line positioned adjacent to the first gas spray part so as to exhaust the first process gas, supplied to the processing space, to an outside of the processing space and converts an exhaust gas, exhausted to the first exhaust line, into a powder form; and a second exhaust part including a second plasma pretreatment part that forms a plasma atmosphere in some areas of a second exhaust line positioned adjacent to the second gas spray part so as to exhaust the second process gas, supplied to the processing space, to the outside of the processing space and converts an exhaust gas, exhausted to the second exhaust line, into a powder form, wherein the exhaust gas-processing method includes: a step (a) of exhausting the first process gas to the first exhaust part; and a step (b) of exhausting the second process gas to the second exhaust part, wherein the step (a) includes a step (a-1) of converting exhaust gas, exhausted to the first exhaust line, into a powder form by operating the first plasma pretreatment part.

According to some embodiments of the present invention, the step (a) may include: a step (a-2) of capturing powder, formed in the first plasma pretreatment part, with a first trap formed after the first plasma pretreatment part; a step (a-3) of capturing residual powder, not captured by the first trap, with a second trap formed after the first trap; and a step (a-4) of sucking exhaust gas inside the processing space and exhausting to an outside of the processing space, using a first pump.

According to some embodiments of the present invention, the exhaust gas-processing method may include: before the step (b), a step (c) of sensing whether the first process gas sprayed from the first gas spray part is introduced into the second exhaust line, through a gas sensor positioned on the second exhaust line.

According to some embodiments of the present invention, the step (b) may include a step (b-1) of turning off the second plasma pretreatment part when the first process gas is not sensed by the gas sensor, and of operating the second plasma pretreatment part when the first process gas is sensed by the gas sensor.

According to some embodiments of the present invention, the step (b) may include: a step (b-2) of capturing powder, formed in the second plasma pretreatment part, with a third trap formed after the second plasma pretreatment part; and a step (b-3) of sucking exhaust gas inside the processing space and exhausting it to an outside of the processing space using a second pump.

### Advantageous Effects

According to an embodiment of the present invention as apparent above, a substrate-processing apparatus in which a plasma pretreatment device capable of processing a source gas when the source gas is exhausted to at least one exhaust line of a plurality of exhaust lines is provided in each exhaust line and which can prevent ignition that may occur after a pump when a source gas is exhausted to one exhaust line of the plural exhaust lines and can control unnecessary electricity use and reduce energy use by operating a plasma pretreatment device when source gas is sensed; and an exhaust gas-processing method using the substrate-processing apparatus can be implemented. Naturally, these effects do not limit the scope of the present invention.

### DESCRIPTION OF DRAWINGS

FIG. 1 illustrates a schematic sectional view of a substrate-processing apparatus according to an embodiment of the present invention.

FIG. 2 is a top view illustrating a showerhead, first exhaust part and second exhaust part of the substrate-processing apparatus according to an embodiment of the present invention.

FIGS. 3 to 6 are flowcharts illustrating an exhaust gas-processing method using a substrate-processing method according to an embodiment of the present invention.

### BEST MODEL

Hereinafter, one or more preferred embodiments of the present invention will be described in detail with reference to the accompanying drawings.

Embodiments of the present invention are provided to more completely explain the present invention to those skilled in the art, and the following embodiments may be modified in many different forms, but the scope of the present invention is not limited to the following embodiments. Rather, the embodiments are provided to make the invention thorough and complete and to fully convey the technical idea of the invention to those skilled in the art. In the drawings, the thicknesses and sizes of layers may be exaggerated for convenience and clarity of explanation.

Hereinafter, the substrate-processing apparatus according to an embodiment of the present invention may be used as a thin film-depositing apparatus for forming a thin film on substrates(S). For example, the substrate-processing apparatus may be used in a thin film-depositing apparatus using atomic layer deposition (ALD). In some embodiments, the substrate-processing apparatus may be applied to a thin film-depositing apparatus requiring a high-temperature process.

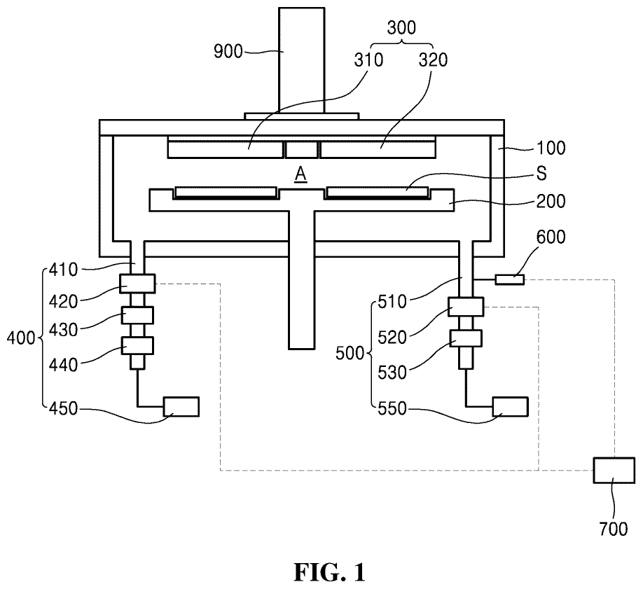

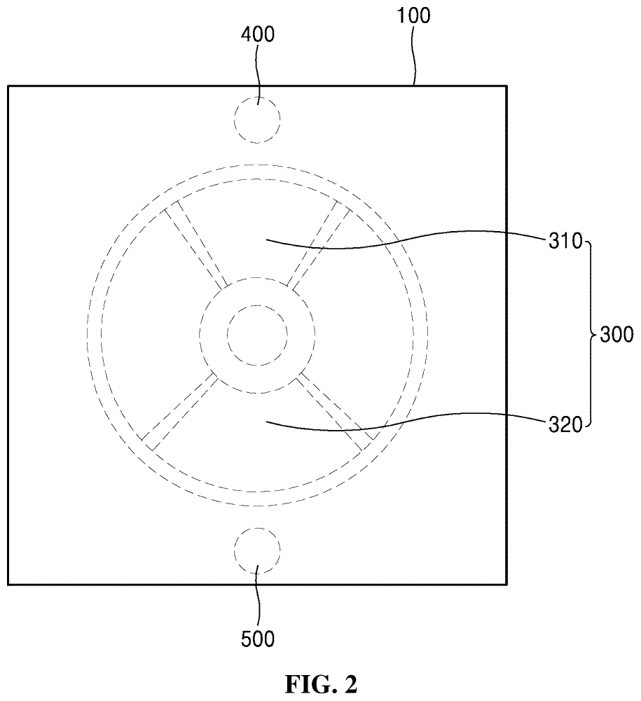

FIG. 1 illustrates a schematic sectional view of a substrate-processing apparatus according to an embodiment of the present invention, and FIG. 2 is a top view illustrating a showerhead, first exhaust part and second exhaust part of the substrate-processing apparatus according to an embodiment of the present invention.

First, the substrate-processing apparatus according to an embodiment of the present invention may largely include a process chamber 100, a substrate support 200, a showerhead 300, a first exhaust part 400 and a second exhaust part 500.

As shown in FIG. 1, the process chamber 100 forms a processing space A for processing substrates.

As shown in FIG. 1, the process chamber 100 may be provided with a processing space A to form a composite film on multiple substrates S. For example, the process chamber 100 may be configured to maintain a sealed state, and may be connected to a vacuum pump through at least one exhaust part so as to discharge process gases to the processing space A and control the vacuum level. A valve for controlling the vacuum level in the process chamber 100 may be formed in at least a portion of the exhaust part, and the valve may be formed in the form of, e.g., a throttle valve to control the amount of air passing through a throttle body.

The exhaust part may include the first exhaust part 400 and the second exhaust part 500, and detailed descriptions thereof are provided below.

The process chamber 100 may be provided in various shapes, and may include, for example, a process chamber body with an open top and a top lid for covering the top of the process chamber body. A gate (not shown), which is a passage for loading or unloading multiple substrates S into the processing space A, may be formed on a side surface of the process chamber body.

As shown in FIG. 1, the substrate support 200 is rotatably formed at a lower part of the processing space A of the process chamber 100, and the multiple substrates S may be radially seated along a rotation direction on the substrate support 200. For example, the substrate support 200 may be installed in the process chamber body to be rotatable based on a rotation axis that coincides with the central axis of the process chamber 100.

For example, the substrate support 200 is sealably coupled to the outside of the process chamber 100 and the inside thereof, and may include a shaft rotating by receiving rotational power; and an upper plate coupled to the shaft. A multiple substrates-to-be-seated part on which the multiple substrates S are seated may be radially arranged on the upper plate. When the multiple substrates S are wafers, the multiple substrates-to-be-seated part may be circular.

The substrate support 200 may be installed in the process chamber 100 to be liftable and/or rotatable.

As shown in FIG. 1, the showerhead 300 may be installed on an upper side of the process chamber 100 to face the substrate support 200. For example, the showerhead 300 may spray a process gas supplied from the outside of the process chamber 100 to the processing space A. More specifically, the showerhead 300 may be formed to spray a process gas to the multiple substrates S seated on the substrate support 200, and may be installed at an upper part of the process chamber 100 to face the substrate support 200.

In some embodiments, the showerhead 300 may include at least one inlet hole formed on the upper layer or side of the showerhead 300 to receive a process gas from the outside; and a plurality of spray holes for spraying a process gas onto the multiple substrates S. For example, the showerhead 300 may include a spray plate having a gas diffusion space thereinside and a spray hole at the bottom, or may be formed in the form of a nozzle.

The showerhead 300 may include a first gas spray part 310 for supplying a first process gas onto the substrate support 200; and a second gas spray part 320 for supplying a second process gas onto the substrate support 200.

Here, the first process gas may be a source gas containing a first organic compound and supplied onto the multiple substrates S so that at least a portion of the first process gas is adsorbed onto the multiple substrates S, and the second process gas may be a reactant gas that does not contain an organic compound and is supplied onto the multiple substrates S, to which the source gas has been adsorbed, to form a deposition film on the multiple substrates S.

As shown in FIG. 1, the showerhead 300 may include the first gas spray part 310 that sprays a source gas to deposit a thin film on the multiple substrates S. For example, at least some units of a plurality of gas spray units formed on the showerhead 300 may be formed as the first gas spray part 310. That is, at least one substrate, which are positioned under the first gas spray part 310, among the multiple substrates S may be supplied with a source gas.

The source gas may be a hydrophobic substance that generates a flammable gas that may spontaneously combust when in contact with water, and may be, for example, a gas containing a substance such as zirconium (Zr) or hafnium (Hf).

In addition, the showerhead 300 may include the second gas spray part 520 that sprays a reactant gas to deposit a thin film on the multiple substrates S. For example, at least another unit of the plural gas spray units formed on the showerhead 300 may be formed as the second gas spray part 320. That is, at least one substrate, positioned under the second gas spray part 320, of the multiple substrates S may be supplied with a reactant gas.

Although not shown, the showerhead 300 may include a purge gas spray part for purging a reactant gas and a source gas on the multiple substrates S. For example, the purge gas spray part may be formed between the first gas spray part 310 and the second gas spray part 320 among the plural gas spray units formed on the showerhead 300, and the first gas spray part 310, the second gas spray part 320 and the purge gas spray part may be arranged to be radially spaced apart FROM EACH OTHER.

Although not shown, in substrate-processing apparatuses according to some embodiments of the present invention, a gas supply part 900 for supplying a process gas sprayed through the showerhead 300 may be formed outside the process chamber 100. In the gas supply part 900, supply parts for respectively supplying a source gas, a reactant gas and a purge gas may be separately formed.

As shown in FIG. 1, the first exhaust part 400 may include a first exhaust line 410 positioned adjacent to the first gas spray part 310 to exhaust the first process gas supplied to the processing space A to the outside of the processing space A.

Here, the first exhaust line 410 being positioned relatively adjacent to the first gas spray part 310 means that the first exhaust line 410 is positioned relatively adjacent to the first gas spray part 310 than the second gas spray part 320.

For example, as shown in FIGS. 1 and 2, the first exhaust part 400 may be formed under the substrate support part 200 at the position where the first gas spray part 310 is formed inside the process chamber 100. Accordingly, the first process gas sprayed from the first gas spray part 310 may be exhausted to the outside of the process chamber 100 through the first exhaust part 400.

The first exhaust part 400 may include a first exhaust line 410, a first plasma pretreatment part 420, a first trap 430, a second trap 440 and a first pump 450.

The first exhaust line 410 may be a pipe connected from the inside of the process chamber 100 to the first pump 450 such that gas may flow through its internal path.

A first throttle valve may be formed on at least a portion of the first exhaust line 410 to control the flow rate of gas flowing through the first exhaust line 410.

The first plasma pretreatment part 420 may form a plasma atmosphere in some areas of the first exhaust line 410 to convert the exhaust gas exhausted through the first exhaust line 410 into a powder form.

The first plasma pretreatment part 420 may convert the first process gas, which is exhausted without reacting, into a stable powder form through decomposition and replacement.

Specifically, only a portion of the source gas, supplied from the processing space A, in the process chamber 100 reacts with the reactant gas to form a film on the multiple substrates S, and the remaining source gas is discharged to the first exhaust line 410. Here, the source gas discharged through the first exhaust line 410 may be made into a stable powder form by the first plasma pretreatment part 420 because it poses a problem for environmental safety if discharged to the atmosphere.

The first trap 430 may be formed after the first plasma pretreatment part 420 and may capture powder formed in the first plasma pretreatment part 420, and the second trap 440 may be formed after the first trap 430 and may capture residual powder not captured in the first trap 430.

The first pump 450 may suck the exhaust gas of the processing space A from the inside of the processing space A through the first exhaust line 410 and exhaust it to the outside of the processing space A.

The first pump 450 may be installed under the process chamber 100 to evacuate the process chamber 100, or may be used as a passage for discharging process gases used in processes.

That is, the first throttle valve that is connected from the inside of the process chamber 100 to the outside of the process chamber 100 through the first exhaust line 410 and controls the flow rate of the exhausted gas based on the process chamber 100; the first plasma pretreatment part 420 that decomposes the first process gas; the first trap 430 that captures powder; the second trap 440 that captures residual powder; and the first pump 450 that sucks gas inside the processing space A through the first exhaust line 410 may be sequentially formed.

The second exhaust part 500 may include the second exhaust line 510 positioned to be adjacent to the second gas spray part 320 to exhaust the second process gas supplied into the processing space A to the outside of the processing space A.

Here, the second exhaust line 510 being positioned relatively adjacent to the second gas spray part 320 means that the second exhaust line 510 is positioned relatively adjacent to the second gas spray part 320 than the first gas spray part 310.

For example, as shown in FIGS. 1 and 2, the second exhaust part 500 may be formed under the process chamber 100 at the position where the second gas spray part 320 is formed inside the process chamber 100. Accordingly, the reactant gas sprayed from the second gas spray part 320 may be exhausted to the outside of the process chamber 100 through the second exhaust part 500.

The second exhaust part 500 may include a second exhaust line 510, a second plasma pretreatment part 520, a third trap 530 and a second pump 550.

The second exhaust line 510 may be a pipe connected from the inside of the process chamber 100 to the second pump 550 such that gas may flow through its internal path.

A second throttle valve may be formed on at least a portion of the second exhaust line 510 to control the flow rate of gas flowing through the second exhaust line 510.

The opening/closing angle of the second throttle valve may vary depending on the opening/closing angle of the first throttle valve. Specifically, when the rotation angle of the first throttle valve is controlled by a controller 700, the opening/closing rate of the second throttle valve may be controlled according to a preset compensation ratio.

For example, when a ratio of the angle of the first throttle valve to the opening/closing angle of the second throttle valve is set to 1:0.5, the angle of the second throttle valve may be opened 20 degrees for operation when the angle of the first throttle valve is opened 40 degrees. For example, when powder is accumulated in the first throttle valve or a lower piping, the first throttle valve is opened more to maintain the vacuum pressure of the processing space A inside the process chamber 100, and the second throttle valve may also be opened more by the set opening/closing angle ratio according to the set opening/closing angle ratio.

Accordingly, by the opening/closing angles of the first throttle valve and the second throttle valve, the flow rate of exhausted gas may be controlled and the balance of the processing space A may be maintained.

The second plasma pretreatment part 520 may form a plasma atmosphere in some areas of the second exhaust line 510 to convert the exhaust gas exhausted through the second exhaust line 510 into a powder form.

The second plasma pretreatment part 520 may convert the exhaust gas, which is exhausted without reacting, into a stable powder form through decomposition and replacement.

Specifically, only a portion of the source gas, supplied from the processing space A, in the process chamber 100 reacts with the reactant gas to form a film on the multiple substrates S, and the remaining source gas is discharged to the first exhaust line 410.

Here, if powder accumulates to a certain extent in the first exhaust line 410, it may not be able to handle the flow rate of the source gas being exhausted even if the first throttle valve is maximally opened, and the source gas may penetrate into the second exhaust line 510 because the second throttle valve of the second exhaust line 510 is opened more than before due to a compensation ratio.

The second plasma pretreatment part 520 may convert the source gas, which has penetrated through the second exhaust line 510, into a stable powder form.

The third trap 530 may be formed after the second plasma pretreatment part 520, and may capture powder formed in the second plasma pretreatment part 520.

The second pump 550 may suck the exhaust gas of the processing space A from the inside of the processing space A through the second exhaust line 510 and exhaust it to the outside of the processing space A.

The second pump 550 may be installed under the process chamber 100 to evacuate the process chamber 100, or may be used as a passage for discharging process gases used in processes.

That is, the second throttle valve that is connected from the inside of the process chamber 100 to the outside of the process chamber 100 through the second exhaust line 510 and controls the flow rate of the exhausted gas based on the process chamber 100; the second plasma pretreatment part 520 that decomposes an infiltrated source gas; the third trap 530 that captures powder; and the second pump 550 that sucks gas inside the processing space A through the second exhaust line 510 may be sequentially formed.

The substrate-processing apparatus according to some embodiments of the present invention may include a gas sensor 600 and a controller 700.

As shown in FIG. 1, the gas sensor 600 is located in the second exhaust line 510 and may detect that the first process gas sprayed from the first gas spray part 310 flows into the second exhaust line 510.

As described above, if the powder accumulates to a certain level in the first exhaust line 410, the source gas may penetrate into the second exhaust line 510. Here, the gas sensor 600 is a sensor that detects whether a source gas has penetrated into the second exhaust line 510.

The gas sensor 600 may be a photoionization detector (PID Sensor) that detects organic compounds that constitute a source gas and a reactant gas. In the photoionization detector, 10.6 eV of energy is released through an extreme ultraviolet lamp (UV lamp) when gas enters a sensor to ionize the gas, and the ionized ions are collected by an electrode to detect a detection current proportional to the concentration of volatile organic compounds (VOCs).

A controller 700 may control the opening/closing angle and opening/closing rate of the first throttle valve formed in the first exhaust line 410 and the second throttle valve formed in the second exhaust line 510.

In addition, the controller 700 may control the operations of the first plasma pretreatment part 420 and the second plasma pretreatment part 520, as shown in FIG. 1.

Specifically, the controller 700 may operate the first plasma pretreatment part 420 to convert the first process gas exhausted through the first exhaust line 410 into powder. In addition, the controller 700 may control the operation of the second plasma pretreatment part 520 depending on whether the gas sensor 600 senses the first process gas.

For example, the controller 700 may disable the second plasma pretreatment part 520 if the first process gas is not detected by the gas sensor 600.

More specifically, the controller 700 detects no first process gas in the gas sensor 600 when the second process gas flows to the second exhaust line 510 and the first process gas does not flow thereto. Here, the second plasma pretreatment part 520 does not operate, and only the second process gas may flow to the second exhaust line 510.

On the other hand, when the first process gas flows together with the second process gas through the second exhaust line 510, the first process gas may be detected by the gas sensor 600. Here, the controller 700 may control the operation of the second plasma pretreatment part 520 to convert the first process gas exhausted through the second exhaust line 510 into a powder form.

Accordingly, even if powder accumulates to a certain level in the first exhaust line 410 and the first process gas penetrates into the second exhaust line 510, it may be converted into powder through the second plasma pretreatment part 520. Accordingly, the first process gas may be prevented from being exhausted to the atmosphere through the second exhaust line 510.

In addition, by controlling the second plasma pretreatment part 520 to operate only when necessary, unnecessary costs and energy waste due to the second plasma pretreatment part 520 may be prevented.

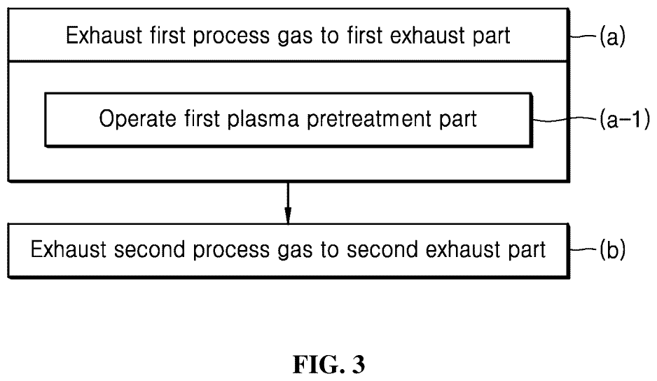

FIGS. 3 to 6 are flowcharts illustrating an exhaust gas-processing method using the substrate-processing method according to an embodiment of the present invention.

The substrate-processing method according to an embodiment of the present invention is an exhaust gas-processing method using a substrate-processing apparatus that includes the process chamber 100 forming the processing space A for substrate processing; the substrate support 200 which is formed under the processing space A, on which the multiple substrates S are seated, and which is rotatable; the showerhead 300 including the first gas spray part 310 which is installed on an upper side of the process chamber 100 to face the substrate support 200 and supplies the first process gas onto the substrate support 200; and the second gas spray part 320 which supplies the second process gas onto the substrate support 200; the first exhaust part 400 including the first plasma pretreatment part 420 that forms a plasma atmosphere in some areas of the first exhaust line 410 positioned adjacent to the first gas spray part 310 so as to exhaust the first process gas, supplied to the processing space A, to the outside of the processing space A and converts an exhaust gas, exhausted to the first exhaust line 410, into a powder form; and the second exhaust part 500 including the second plasma pretreatment part 520 that forms a plasma atmosphere in some areas of the second exhaust line 510 positioned adjacent to the second gas spray part 320 so as to exhaust the second process gas, supplied to the processing space A, to the outside of the processing space A and converts an exhaust gas, exhausted to the second exhaust line 510, into a powder form.

Specifically, as shown in FIG. 1, the exhaust gas-processing method may include a step (a) of exhausting the first process gas to the first exhaust part 400; and a step (b) of exhausting the second process gas to the second exhaust part 500.

In the step (a), the multiple substrates S may be seated on the substrate support 200 and the first process gas and second process gas sprayed from the showerhead 300 may be supplied to the multiple substrates S. Here, only a portion of the supplied first process gas reacts with the second process gas to form a film on the multiple substrates S, and the residual first process gas may be discharged to the first exhaust line 410.

Specifically, the step (a) may include a step (a-1) of operating the first plasma pretreatment part 420, a step (a-2) of capturing powder with the first trap 430, a step (a-3) of capturing residual powder with the second trap 440 and a step (a-4) of exhausting exhaust gas with the first pump 450.

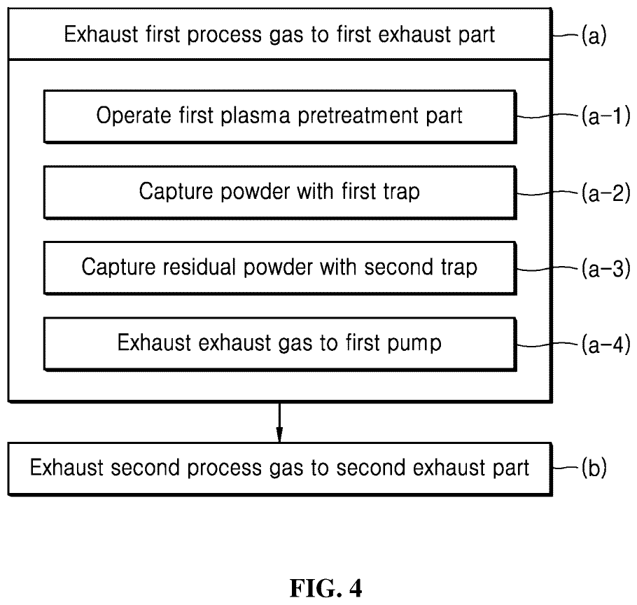

As shown in FIGS. 3 and 4, the step (a-1) is a step of converting the exhaust gas exhausted to the first exhaust line 410 into a powder form by operating the first plasma pretreatment part 420.

As described above, in the step (a), only a portion of the first process gas, supplied from the processing space A, in the process chamber 100 reacts with the second process gas to form a film on the multiple substrates S, the residual first process gas is discharged to the first exhaust line 410.

Accordingly, since the first process gas discharged to the first exhaust line 410 in the step (a-1) may cause environmental safety problems if discharged into the atmosphere, the first process gas may be converted into a stable powder form through the first plasma pretreatment part 420.

The first process gas may include a source gas adsorbed on the multiple substrates S, and the second process gas may include a reactant gas for forming a deposition film on the multiple substrates S to which the first process gas has been adsorbed.

The step (a-2) is a step of capturing the powder, formed in the first plasma pretreatment part 420, with the first trap 430 formed after the first plasma pretreatment part 420, and the step (a-3) is a step of capturing the residual powder, not captured by the first trap 430, with the second trap 440 formed after the first trap 430.

The step (a-4) is a step of sucking the exhaust gas inside the processing space A and exhausting it outside the processing space A using the first pump 450.

In the step (a-4), the first pump 450 may be provided under the process chamber 100 and may evacuate the process chamber 100 or discharge the process gas used in the processes.

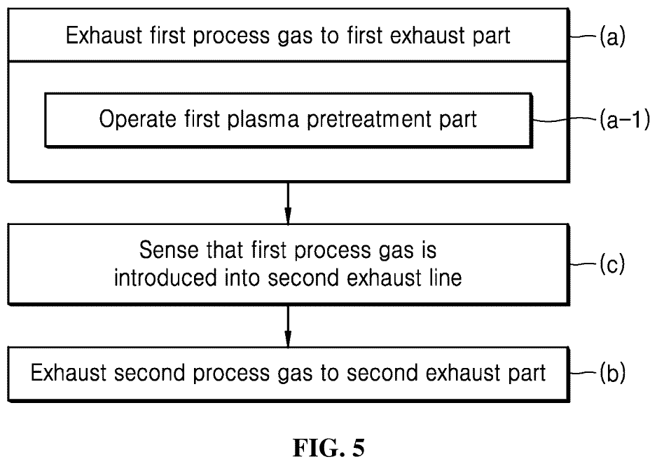

The exhaust gas-processing method according to some embodiments of the present invention may include a step (c) of, before the step (b), sensing whether the first process gas flows into the second exhaust line 510, as shown in FIG. 5.

Specifically, the step (c) is a step of detecting, through the gas sensor 600 located in the second exhaust line 510, that the first process gas sprayed from the first gas spray part 310 flows into the second exhaust line 510. For example, when a certain amount of powder accumulates in the first exhaust line 410, the first process gas may penetrate into the second exhaust line 510. Here, in the step (c), the gas sensor 600 may detect whether the first process gas penetrates into the second exhaust line 510.

For example, the step (c) may be performed during the step (a). That is, the step (c) of sensing whether the first process gas flows into the second exhaust line 510 may be performed during the step (a) of exhausting the first process gas to the first exhaust part 400.

The step (c) may be continuously performed during the step (a) to continuously detect whether the first process gas flows into the second exhaust line 510, or the step (c) may be repeatedly performed during the step (a) to detect whether the first process gas flows into the second exhaust line 510 at predetermined time intervals.

In addition, the step (c) may be continuously performed during the step (b). Accordingly, in the step (c), the operation of the second plasma pretreatment part 520 may be stopped when the first process gas is not sensed in the second exhaust line 510.

The step (b) is a step of exhausting the second process gas to the second exhaust part 500.

In the step (b), the multiple substrates S may be seated on the substrate support 200 so that the first process gas and second process gas sprayed from the showerhead 300 may be supplied to the multiple substrates S. Here, only a portion of the supplied second process gas reacts with the first process gas to form a film on the multiple substrates S, and the residual second process gas may be discharged to the second exhaust line 510.

For example, the step (b) is a step of exhausting the second process gas to the second exhaust part 500 when processing the multiple substrates S and may be performed during or after the step (a).

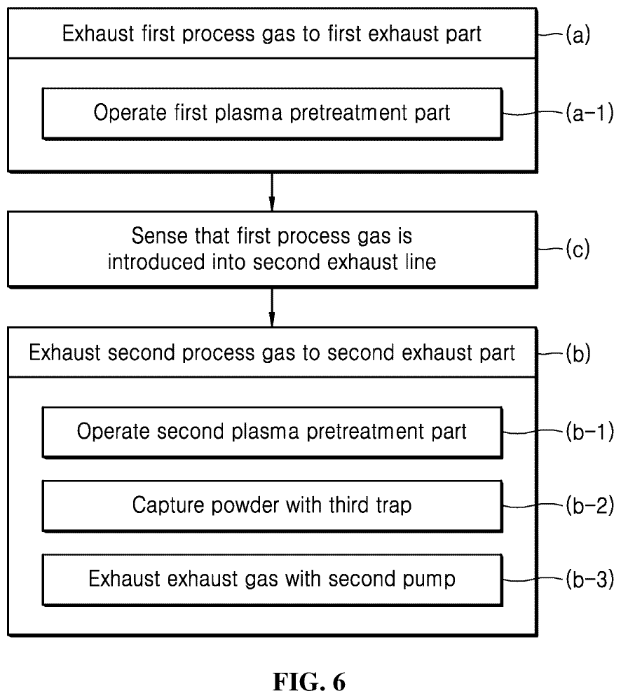

Specifically, the step (b) may include a step (b-1) of operating the second plasma pretreatment part 520, a step (b-2) of capturing powder with the third trap 530 and a step (b-3) of exhausting exhaust gas to the second pump 550, as shown in FIG. 6.

In the step (b-1), the second plasma pretreatment part 520 may be turned off when the first process gas is not sensed by the gas sensor 600.

As described above, in the step (b), only a portion of the second process gas, supplied from the processing space A, in the process chamber 100 reacts with the first process gas to form a film on the multiple substrates S, and the residual second process gas is discharged to the second exhaust line 510.

Here, when the first process gas is not contained in the gas discharged to the second exhaust line 510, the second process gas may be exhausted without operating the second plasma pretreatment part 520.

Alternatively, in the step (b-1), the second plasma pretreatment part 520 may be operated when the first process gas is sensed by the gas sensor 600.

Specifically, in the step (a), the first process gas is exhausted to the first exhaust part 400, but if a certain amount of powder accumulates in the first exhaust line 410, the flow rate of the exhausted first process gas may not be processed, and the first process gas of the second exhaust line 510 may penetrate.

Accordingly, the first process gas in the second exhaust line 510 is sensed in the step (c), and, accordingly, the second plasma pretreatment part 520 formed in the second exhaust line 510 is operated in the step (b-1).

That is, the step (b-1) is a step for converting a first process gas into a stable powder form through the second plasma pretreatment part 520 because the first process gas discharged into the second exhaust line 510 may cause environmental safety problems if discharged into the atmosphere.

The step (b-2) is a step of capturing the powder formed in the second plasma pretreatment part 520 with the third trap 530 formed after the second plasma pretreatment part 520.

The step (b-3) is a step of sucking exhaust gas inside the processing space A and exhausting it outside the processing space A using the second pump 550.

In the step (b-3), the second pump 550 may be installed under the process chamber 100 to evacuate the process chamber 100 or to discharge the process gas used in the processes.

According to the substrate-processing apparatus and exhaust gas-processing method of the present invention, the first plasma pretreatment part 420 and second plasma pretreatment part 520 capable of processing a source gas when a source gas is exhausted to the first exhaust line 410 and the second exhaust line 510 are provided in exhaust lines, respectively, and when the source gas is exhausted to the first exhaust line 410, ignition that may occur after the first pump 450 may be prevented.

In addition, when the source gas is detected in the second exhaust line 510, the second plasma pretreatment part 520 is operated to process the source gas exhausted to the second pump 550 and prevent ignition, and the second plasma pretreatment part 520 may be selectively operated to prevent unnecessary electricity use.

Although the present invention has been described with reference to embodiments shown in the drawings, the embodiments are provided as only exemplary examples, and those skilled in the art will understand that various modifications and equivalent other embodiments are possible therefrom. Therefore, the true technical protection scope of the present invention should be determined by the technical spirit of the appended claims.

1. A substrate-processing apparatus, comprising:
a process chamber that forms a processing space for substrate processing;
a substrate support which is formed at a lower part of the processing space, on which multiple substrates are seated and which is rotatable;
a showerhead which is installed on an upper side of the process chamber to face the substrate support and comprises a first gas spray part for supplying a first process gas onto the substrate support and a second gas spray part for supplying a second process gas onto the substrate support;
a first exhaust part comprising a first exhaust line that is positioned adjacent to the first gas spray part to exhaust the first process gas, supplied to the processing space, to an outside of the processing space; and
a second exhaust part comprising a second exhaust line that is positioned adjacent to the second gas spray part to exhaust the second process gas, supplied to the processing space, to an outside of the processing space,
wherein the first exhaust part comprises a first plasma pretreatment part that forms a plasma atmosphere in some areas of the first exhaust line and converts exhaust gas exhausted to the first exhaust line into a powder form, and
the second exhaust part comprises a second plasma pretreatment part that forms a plasma atmosphere in some areas of the second exhaust line and converts exhaust gas exhausted to the second exhaust line into a powder form.

2. The substrate-processing apparatus according to claim 1, wherein the first exhaust part comprises:
a first trap formed after the first plasma pretreatment part and configured to capture powder formed in the first plasma pretreatment part;
a second trap formed after the first trap and configured to capture residual powder that is not captured by the first trap; and
a first pump configured to suck exhaust gas of the processing space from an inside of the processing space and exhaust it to an outside of the processing space, through the first exhaust line.

3. The substrate-processing apparatus according to claim 1, wherein the second exhaust part comprises:
a third trap formed after the second plasma pretreatment part and configured to capture powder formed in the second plasma pretreatment part; and
a second pump configured to suck exhaust gas of the processing space from an inside of the processing space and exhaust it to an outside of the processing space, through the second exhaust line.

4. The substrate-processing apparatus according to claim 1, comprising a gas sensor located at the second exhaust line and configured to sense that the first process gas sprayed from the first gas spray part is introduced into the second exhaust line.

5. The substrate-processing apparatus according to claim 4, comprising a controller configured to control an operation of the second plasma pretreatment part depending upon whether the first process gas is sensed by the gas sensor.

6. The substrate-processing apparatus according to claim 5, wherein the controller turns off the second plasma pretreatment part when the first process gas is not sensed by the gas sensor, and operates the second plasma pretreatment part such that the first process gas exhausted to the second exhaust line is converted into a powder form when the first process gas is sensed by the gas sensor.

7. An exhaust gas-processing method using a substrate-processing apparatus, the substrate-processing apparatus comprising: a process chamber forming a processing space for substrate processing; a substrate support which is formed under the processing space, on which multiple substrates S are seated, and which is rotatable; a showerhead comprising a first gas spray part which is installed on an upper side of the process chamber to face the substrate support and supplies a first process gas onto the substrate support; and a second gas spray part which supplies a second process gas onto the substrate support; a first exhaust part comprising a first plasma pretreatment part that forms a plasma atmosphere in some areas of a first exhaust line positioned adjacent to the first gas spray part so as to exhaust the first process gas, supplied to the processing space, to an outside of the processing space and converts an exhaust gas, exhausted to the first exhaust line, into a powder form; and a second exhaust part comprising a second plasma pretreatment part that forms a plasma atmosphere in some areas of a second exhaust line positioned adjacent to the second gas spray part so as to exhaust the second process gas, supplied to the processing space, to the outside of the processing space and converts an exhaust gas, exhausted to the second exhaust line, into a powder form,
wherein the exhaust gas-processing method comprises:
a step (a) of exhausting the first process gas to the first exhaust part; and
a step (b) of exhausting the second process gas to the second exhaust part,
wherein the step (a) comprises a step (a-1) of converting exhaust gas, exhausted to the first exhaust line, into a powder form by operating the first plasma pretreatment part.

8. The exhaust gas-processing method according to claim 7, wherein the step (a) comprises:
a step (a-2) of capturing powder, formed in the first plasma pretreatment part, with a first trap formed after the first plasma pretreatment part;
a step (a-3) of capturing residual powder, not captured by the first trap, with a second trap formed after the first trap; and
a step (a-4) of sucking exhaust gas inside the processing space and exhausting to an outside of the processing space, using a first pump.

9. The exhaust gas-processing method according to claim 7, comprising: before the step (b), a step (c) of sensing whether the first process gas sprayed from the first gas spray part is introduced into the second exhaust line, through a gas sensor positioned on the second exhaust line.

10. The exhaust gas-processing method according to claim 9, wherein the step (b) comprises a step (b-1) of turning off the second plasma pretreatment part when the first process gas is not sensed by the gas sensor, and of operating the second plasma pretreatment part when the first process gas is sensed by the gas sensor.

11. The exhaust gas-processing method according to claim 7, wherein the step (b) comprises:
a step (b-2) of capturing powder, formed in the second plasma pretreatment part, with a third trap formed after the second plasma pretreatment part; and
a step (b-3) of sucking exhaust gas inside the processing space and exhausting it to an outside of the processing space using a second pump.
